(19) United States
(12) Patent Application Publication
(10) Pub. No.: US 2002/0167034 A1
(43) Pub. Date: Nov. 14, 2002

(54) Semiconductor device evaluation method and apparatus, semiconductor device manufacturing control method, semiconductor device manufacturing method, and recording medium

(75) Inventors: Kenji Yamaguchi, Tokyo (JP); Hiroyuki Amishiro, Tokyo (JP); Motoshige Igarashi, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MITSUBISHI DENKI KABUSHIKI KAISHA, TOKYO (JP)

(21) Appl. No.: 09/955,080

(22) Filed: Sep. 19, 2001

(30) Foreign Application Priority Data
May 9, 2001 (JP) P2001-138712

(51) Int. Cl. H01L 27/108; H01L 29/76; H01L 29/94; H01L 31/119

(52) U.S. Cl. 257/296

(57) ABSTRACT

A semiconductor device evaluation method and apparatus are provided which do not require a measurer to expend a great deal of time and effort even when measuring a large number of points, can prevent the occurrence of variations in measured values from measurer to measurer, and allow the measurement of the finished gate length even if gate pattern does not appear on the semiconductor device surface. There is also provided a semiconductor device manufacturing control method which applies such an evaluation method and apparatus to the control of semiconductor device manufacturing. For a plurality of insulated gate transistors with different channel lengths, an effective channel length (Leff), a gate capacitance (Cg), and a fringing capacitance (Cf) are determined by electrical measurement and/or calculation. The gate capacitance (Cg) and the effective channel length (Leff) are extended on a graph by extrapolation to determine gate-capacitance-vs.-effective-channel-length characteristics. Then, a gradient (A) of the characteristics is calculated to determine the finished gate length (Lg) for each of the plurality of insulated gate transistors from the equation, Lg=(Cg−Cf)/A.

### BACKGROUND OF THE INVENTION

1. Field of the Invention

The present invention relates to a semiconductor device evaluation method and apparatus for evaluating a gate length of an insulated gate transistor such as a MOSFET (metal oxide semiconductor field effect transistor) and also relates to a semiconductor device manufacturing control method and a semiconductor device manufacturing method which apply such an evaluation method and apparatus to the control of semiconductor device manufacturing and to the manufacture of semiconductor devices.

2. Description of the Background Art

In advanced development in insulated gate transistor devices, one important challenge is to evaluate gate lengths of those devices with accuracy.

As the gate length has been reduced year after year, the finished dimension of the gate after machining is more likely to vary. Since variations in the gate length constitute the main factor of variations in circuit characteristics, it is necessary to measure the finished gate length with high accuracy and to analyze how the gate length correlates with the circuit characteristics of the device.

Conventionally, the finished gate length has been measured by a scanning electron microscope (hereinafter referred to as a “SEM”). A measurer has checked the finished gate length of each insulated gate transistor on a display screen, against a scale on the same display screen.

Such measurements of the finished gate length by the SEM, however, involve the following problems:

(1) For each element, the finished gate length must be visually checked against the scale on the display screen. This requires a measurer to expend a great deal of time and effort when measuring a large number of points.

(2) A visual check of the finished gate length causes variations in measured values from measurer to measurer.

(3) Measurements cannot be performed if gate pattern does not appear on the semiconductor device surface.

### SUMMARY OF THE INVENTION

A first aspect of the present invention is directed to a semiconductor device evaluation method comprising the steps of: (a) for a plurality of insulated gate transistors with different channel lengths, determining an effective channel length Leff, a gate capacitance Cg which is a capacitance between a gate and a substrate, and a fringing capacitance Cf which is a capacitance between the gate and a portion of the substrate not covered with the gate, by electrical measurement and/or calculation; (b) plotting the gate capacitance Cg and the effective channel length Leff, which have been determined in the step (a), on a graph and extending the same by extrapolation on the graph to determine gate-capacitance-vs.-effective-channel-length characteristics; and (c) calculating a gradient A of the gate-capacitance-vs.-effective-channel-length characteristics and determining a finished gate length Lg for each of the plurality of insulated gate transistors from the equation, Lg=(Cg−Cf)/A.

According to a second aspect of the present invention, in the semiconductor device evaluation method of the first aspect, the step (a) prepares a design gate length Ld instead of determining the effective channel length Leff by electrical measurement and/or calculation, the step (b) plots the gate capacitance Cg and the design gate length Ld, which have been determined in the step (a), on a graph and extends the same by extrapolation on the graph to determine gate-capacitance-vs.-design-gate-length instead of determining the gate-capacitance-vs.-effective-channel-length characteristics, and the step (c) calculates a gradient of the gate-capacitance-vs.-design-gate-length characteristics as the gradient A, instead of calculating the gradient of the gate-capacitance-vs.-effective-channel-length characteristics.

According to a third aspect of the present invention, in the semiconductor device evaluation method of the first or second aspect, the step (b) carries out the extrapolation of the characteristics by linear approximation.

According to a fourth aspect of the present invention, the semiconductor device evaluation method of the first aspect further comprises the steps of: (d) determining an intercept B of the gate-capacitance-vs.-effective-channel-length characteristics; and (e) for the plurality of insulated gate transistors, determining a gate overlap capacitance CGDO which is a capacitance between the gate and a source/drain region covered with the gate, from the equation, CGDO=B/(2·W)−Cf, by using a gate width W of the gate.

According to a fifth aspect of the present invention, the semiconductor device evaluation method of the first or second aspect further comprises the step of: (f) for the plurality of insulated gate transistors, determining an effective gate insulating film thickness Toxeff from the equation, Toxeff=W·εox/A, by using the gradient A, a gate width W of the gate, and the permittivity εox of a gate insulating film.

A sixth aspect of the present invention is directed to a computer-readable recording medium for recording a program which is executed by a computer either by itself or in combination with a preinstalled program in the computer, to carry out the semiconductor device evaluation method of either of the first through fifth aspects.

A seventh aspect of the present invention is directed to a semiconductor device evaluation apparatus comprising: a calculation section for, for a plurality of insulated gate transistors with different channel lengths, plotting an effective channel length Leff and a gate capacitance Cg which is a capacitance between a gate and a substrate, on a graph and extending the same by extrapolation on the graph to determine gate-capacitance-vs.-effective-channel-length characteristics, and calculating a gradient A of the characteristics; a first determination section for determining a finished gate length Lg for each of the plurality of insulated gate transistors from the equation, Lg=(Cg−Cf)/A, by using a fringing capacitance Cf which is a capacitance between the gate and a portion of the substrate not covered with the gate, the gradient A, and the gate capacitance Cg; and a control section for controlling the calculation section and the first determination section.

According to an eighth aspect of the present invention, in the semiconductor device evaluation apparatus of the seventh aspect, the calculation section uses a design gate length Ld instead of the effective channel length Leff, the calculation section plots the gate capacitance Cg and the design gate length Ld on a graph and extends the same by extrapolation on the graph to determine gate-capacitance-vs.-design-gate-length characteristics, instead of determining the gate-capacitance-vs.-effective-channel-length characteristics, and the calculation section calculates a gradient of the gate-capacitance-vs.-design-gate-length characteristics as the gradient A, instead of calculating the gradient of the gate-capacitance-vs.-effective-channel-length characteristics.

According to a ninth aspect of the present invention, in the semiconductor device evaluation apparatus of the seventh or eighth aspect, the calculation section carries out the extrapolation of the characteristics by linear approximation.

According to a tenth aspect of the present invention, in the semiconductor device evaluation apparatus of the seventh aspect, the calculation section further determines an intercept B of the gate-capacitance-vs.-effective-channel-length characteristics. The apparatus further comprises: a second determination section for, for the plurality of insulated gate transistors, determining a gate overlap capacitance CGDO which is a capacitance between the gate and a source/drain region covered with the gate, from the equation, CGDO=B/(2·W)−Cf, by using a gate width W of the gate, wherein the second determination section is also controlled by the control section.

According to an eleventh aspect of the present invention, in the semiconductor device evaluation apparatus of the seventh or eighth aspect further comprises: a third determination section for, for the plurality of insulated gate transistors, determining an effective gate insulating film thickness Toxeff from the equation, Toxeff=W·εox/A, by using the gradient A, a gate width W of the gate, and the permittivity εox of a gate insulating film, wherein the third determination section is also controlled by the control section.

A twelfth aspect of the present invention is directed to a semiconductor device evaluation method comprising the steps of: (a) while regarding a plurality of insulated gate transistors with different gate length as a plurality of resistive elements with different line widths Lg each using a gate as a resistance, determining the line width Lg for some of the plurality of resistive elements; (b) for all of the plurality of resistive elements, determining a resistance Rg of the gate and an effective channel length Leff by electrical measurement and/or calculation; (c) plotting the line width Lg and the effective channel length Leff, which have been determined in the steps (a) and (b), on a graph and extending the same by extrapolation on the graph to determine line-width-vs.-effective-channel-width characteristics; and (d) for all of the plurality of resistive elements, determining characteristics between the line width Lg and the resistance Rg by using the line-width-vs.-effective-channel-length characteristics.

A thirteenth aspect of the present invention is directed to a semiconductor device evaluation method comprising the steps of: (g) preparing a finished gate length Lg determined by the semiconductor device evaluation method of the first or second aspect; (h) for each of the plurality of insulated gate transistors, determining a resistance Rg of a gate by electrical measurement and/or calculation; and (i) determining characteristics between the finished gate length Lg and the resistance Rg.

A fourteenth aspect of the present invention is directed to a computer-readable recording medium for recording a program which is executed by a computer either by itself or in combination with a preinstalled program in the computer, to carry out the semiconductor device evaluation method of the twelfth or thirteenth aspect.

A fifteenth aspect of the present invention is directed to a semiconductor device evaluation apparatus comprising: a calculation section for, while regarding a plurality of insulated gate transistors with different channel lengths as a plurality of resistive elements with different line widths Lg each using a gate as a resistance, plotting an effective channel length Leff and the line width Lg for some of the plurality of resistive elements on a graph and extending the same by extrapolation on the graph to determine line-width-vs.-effective-channel-length characteristics; a determination section for, for all of the plurality of resistive elements, determining characteristics between the line width Lg and a resistance Rg of the gate by using the line-width-vs.-effective-channel-length characteristics; and a control section for controlling the calculation section and the determination section.

A sixteenth aspect of the present invention is directed to a semiconductor device evaluation apparatus comprising: a determination section for determining characteristics between a finished gate length Lg obtained by the semiconductor device evaluation method of the first or second aspect, and a resistance Rg of a gate for each of the plurality of insulated gate transistors; and a control section for controlling the determination section.

A seventeenth aspect of the present invention is directed to a semiconductor device manufacturing control method comprising: a judgment step for judging whether the finished gate length Lg of each of the plurality of insulated gate transistors, obtained by the semiconductor device evaluation method of either of the first through fifth aspects, or the twelfth or thirteenth aspect, meets required standard, wherein a result of judgment in the judgment step is utilized for reappraisal of manufacturing conditions of semiconductor devices.

An eighteenth aspect of the present invention is directed to a semiconductor device manufacturing method comprising a judgment step for judging whether the finished gate length Lg of each of the plurality of insulated gate transistors, obtained by the semiconductor device evaluation method of either of the first through fifth aspects, or the twelfth or thirteenth aspect, meets required standards, wherein a result of judgment in the judgment step is utilized for rejection of nonconforming products.

In the first aspect of the present invention, the gate-capacitance-vs.-effective-channel-length characteristics are determined by extrapolation and the gate finished length is determined from the gradient of the characteristics. That is, measurements can be performed without a visual check, unlike conventional SEM measurements. This allows easy determination of the finished gate length and prevents a measurer from being forced to expend a great deal of time and effort when measuring a large number of points. Such measurements without a visual check can also prevent the occurrence of variations in measured values from measurer to measurer and allow the determination of the finished gate length even when gate pattern does not appear on the semiconductor device surface.

In the second aspect of the present invention, the finished gate length Lg is determined from the design gate length Ld instead of the effective channel length Leff. This achieves similar effect to that of the first aspect.

In the third aspect of the present invention, the extrapolation of the characteristics is carried out by linear approximation. This allows easy determination of the gradient A of the characteristics and thereby accelerates the determination of the finished gate length.

The fourth aspect of the present invention allows easy determination of the gate overlap capacitance CGDO.

The fifth aspect of the present invention allows easy determination of the effective gate insulating film thickness Toxeff.

According to the sixth aspect of the present invention, the semiconductor device evaluation method set forth in either of the first through fifth aspects can be achieved by a computer.

The seventh aspect of the present invention provides the evaluation apparatus which achieves the semiconductor device evaluation method of the first aspect.

The eighth aspect of the present invention provides the evaluation apparatus which achieves the semiconductor device evaluation method of the second aspect.

The ninth aspect of the present invention provides the evaluation apparatus which achieves the semiconductor device evaluation method of the third aspect.

The tenth aspect of the present invention provides the evaluation apparatus which achieves the semiconductor device evaluation method of the fourth aspect.

The eleventh aspect of the present invention provides the evaluation apparatus which achieves the semiconductor device evaluation method of the fifth aspect.

In the twelfth aspect of the present invention, the line-width-vs.-effective-channel-length characteristics for some of the plurality of resistive elements are used to determine the characteristics between the line width Lg and the resistance Rg for all of the plurality of resistive elements. This allows easy checking of whether all of the plurality of resistive elements have been manufactured properly.

In the thirteenth aspect of the present invention, the characteristics between the finished gate length Lg and the resistance Rg are determined by using the finished gate length Lg obtained by the semiconductor device evaluation method of the first or second aspect. This allows easy checking of whether the plurality of insulated gate transistors have been manufactured properly.

According to the fourteenth aspect of the present invention, the semiconductor device evaluation method of the twelfth or thirteenth aspect can be achieved by a computer.

The fifteenth aspect of the present invention provides the evaluation apparatus which achieves the semiconductor device evaluation method of the twelfth aspect.

The sixteenth aspect of the present invention provides the evaluation apparatus which achieves the semiconductor device evaluation method of the thirteenth aspect.

In the seventeenth aspect of the present invention, the result of judgment in the judgment step is utilized for reappraisal of manufacturing conditions of semiconductor devices. This allows easy checking and reappraisal of manufacturing conditions.

The eighteenth aspect of the present invention allows easy checking for nonconforming products.

An object of the present invention is to provide a semiconductor device evaluation method and apparatus which do not require a measurer to expend a great deal of time and effort when measuring a large number of points, can prevent the occurrence of variations in measured values from measurer to measurer, and allow the measurement of the finished gate length even if gate pattern does not appear on the semiconductor device surface. The present invention also provides a semiconductor device manufacturing control method and a semiconductor device manufacturing method which apply such an evaluation method and apparatus to the control of semiconductor device manufacturing and to the manufacture of semiconductor devices.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view showing a structure of an insulated gate transistor which is an object to be measured;

FIG. 2 is a flowchart of a semiconductor device evaluation method according to a first preferred embodiment;

FIG. 3 illustrates a plot of gate-capacitance-vs.-effective-channel-length characteristics;

FIG. 4 is a flowchart illustrating a modification of the semiconductor device evaluation method of the first preferred embodiment;

FIG. 5 illustrates a plot of gate-capacitance-vs.-effective-channel-length characteristics;

FIG. 6 illustrates a semiconductor device evaluation apparatus according to the first preferred embodiment;

FIG. 7 illustrates a plot of measured results by a SEM and calculated results by the semiconductor device evaluation method of the first preferred embodiment;

FIG. 8 is a flowchart of a semiconductor device manufacturing control method which applies the semiconductor device evaluation method of the first preferred embodiment;

FIG. 9 is a top view showing a structure of an insulated gate transistor which is an object to be measured;

FIG. 10 is a flowchart of a semiconductor device evaluation method according to a second preferred embodiment;

FIG. 11 illustrates a plot of line-width-vs.-effective-channel-length characteristics;

FIG. 12 is a flow chart illustrating a modification of the semiconductor device evaluation method of the second preferred embodiment;

FIGS. 13 and 14 illustrate semiconductor device evaluation apparatuses according to the second preferred embodiment; and

FIG. 15 illustrates a plot of characteristics between the finished gate length Lg and the resistance Rg, obtained by the semiconductor device evaluation method of the second preferred embodiment.

### DESCRIPTION OF THE PREFERRED EMBODIMENTS

### First Preferred Embodiment

In this preferred embodiment, for each of a plurality of insulated gate transistors with different channel lengths, parameters including an effective channel length Leff, a gate capacitance Cg, and a fringing capacitance Cf are determined and used to determine a finished gate length Lg. This provides a semiconductor device evaluation method and apparatus which do not require a measurer to expend a great deal of time and effort when measuring a large number of points, can prevent the occurrence of variations in measured values from measurer to measurer, and allow the measurement of the finished gate length even if gate pattern does not appear on the semiconductor device surface. By applying such an evaluation method and apparatus to the control of semiconductor device manufacturing, a semiconductor device manufacturing control method which allows easy reappraisal of manufacturing conditions can also be achieved.

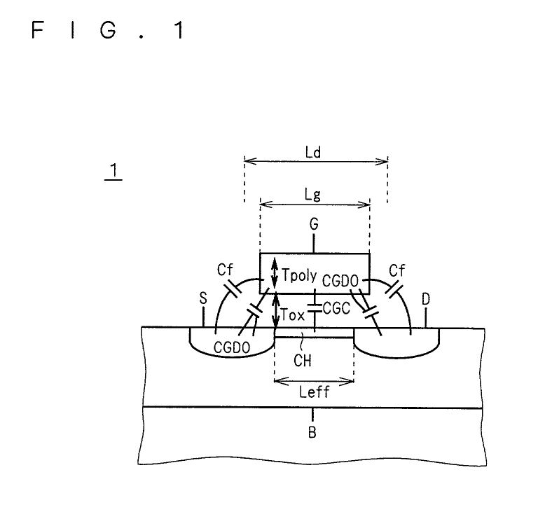

FIG. 1 is a cross-sectional view showing a structure of an insulated gate transistor 1 which is an object to be measured. In FIG. 1, a well B is formed in a substrate, and a source region S and a drain region D are formed in the well B. On the surface of the substrate, a gate G is formed with a gate insulating film (not shown) sandwiched in between. A region CH for formation of a channel layer is located just under the gate G.

In FIG. 1, the film thicknesses of the gate G and the gate insulating film are indicated by Tpoly and Tox, respectively. The distance of the channel layer formed between the edges of the source/drain regions S and D is indicated as an effective channel length Leff; the finished length of the gate G after manufacturing as a finished gate length Lg; and the design length of the gate G as a design gate length Ld.

FIG. 1 further shows electrostatic capacitance between the gate and the substrate at each point, including a fringing capacitance Cf between the gate G and a portion of the substrate not covered with the gate G, a gate overlap capacitance CGDO between the gate G and the source/drain region covered with the gate G, and a channel capacitance CGC between the gate G and the channel layer.

FIG. 9 is a top view of the structure of the insulated gate transistor 1. In FIG. 9, W is the gate width of the gate G and Wa is the length of the gate G itself.

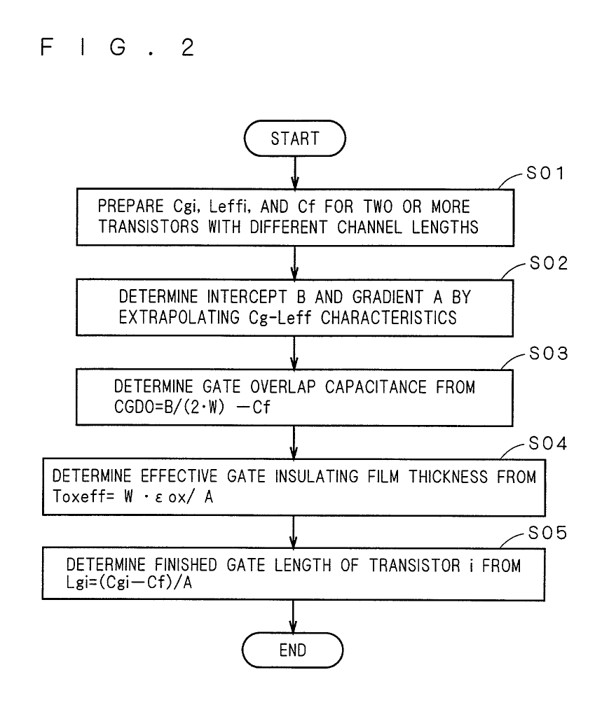

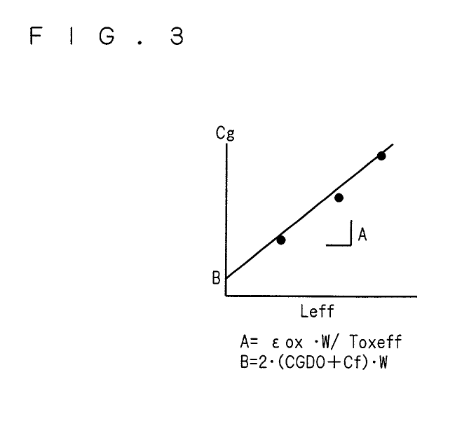

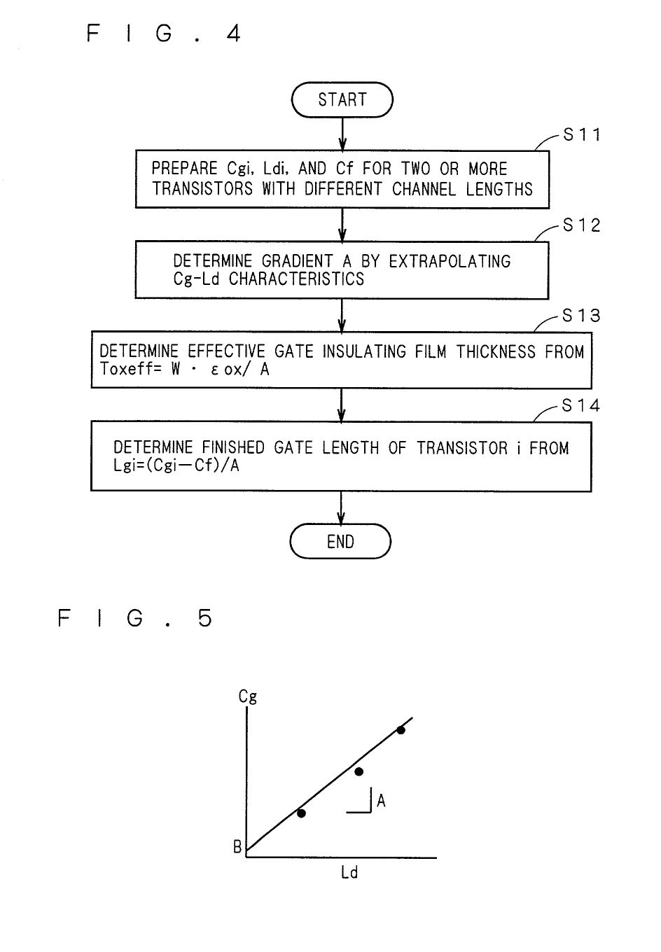

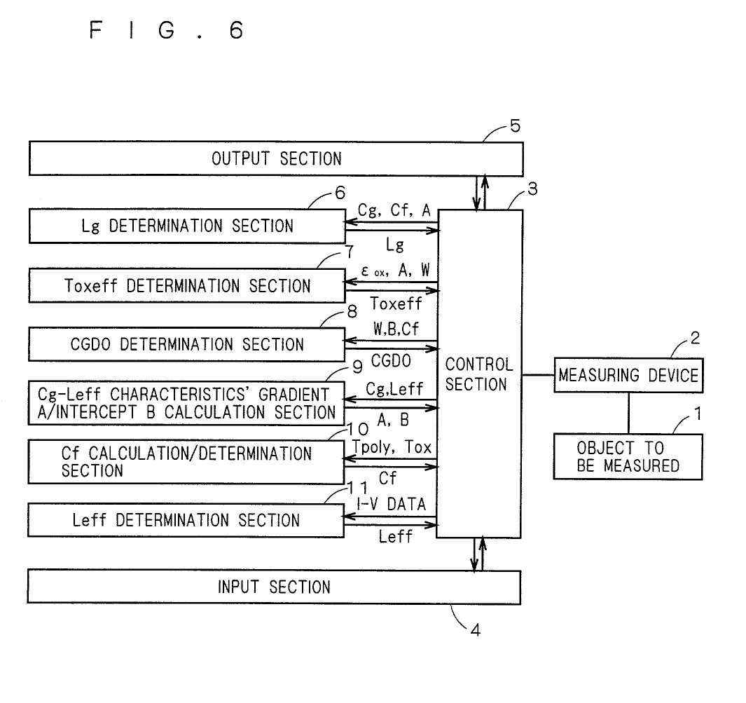

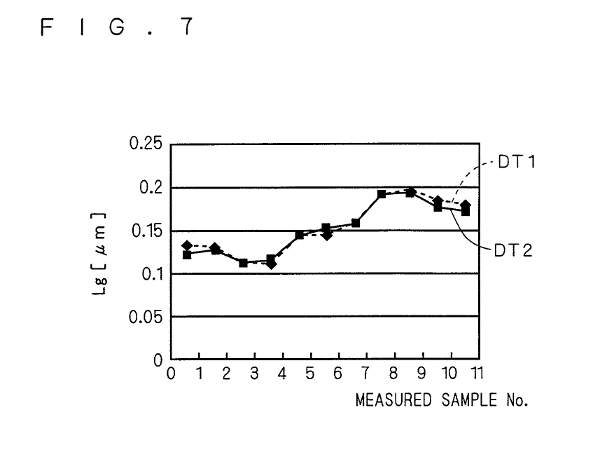

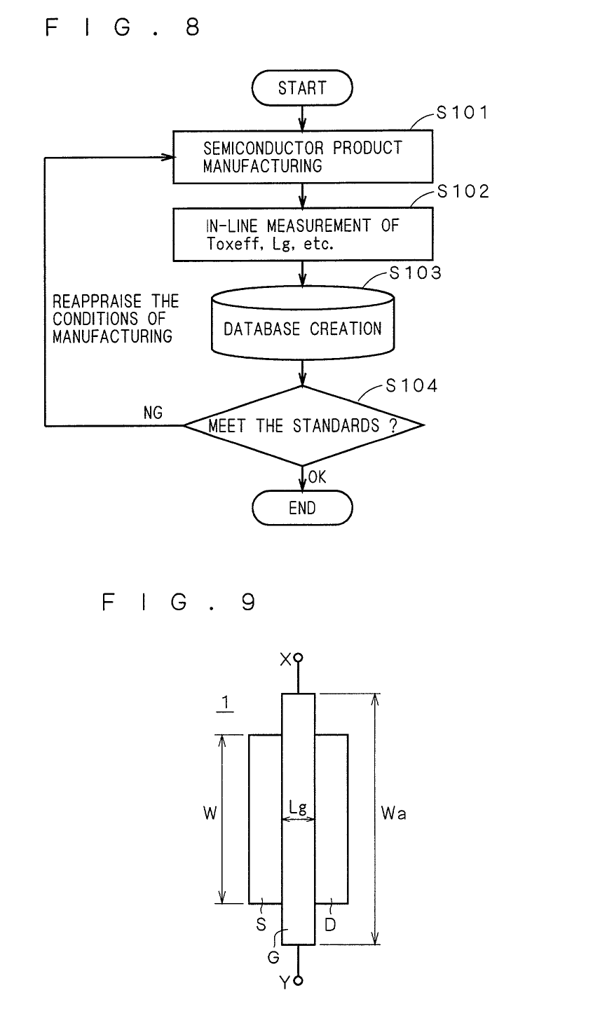

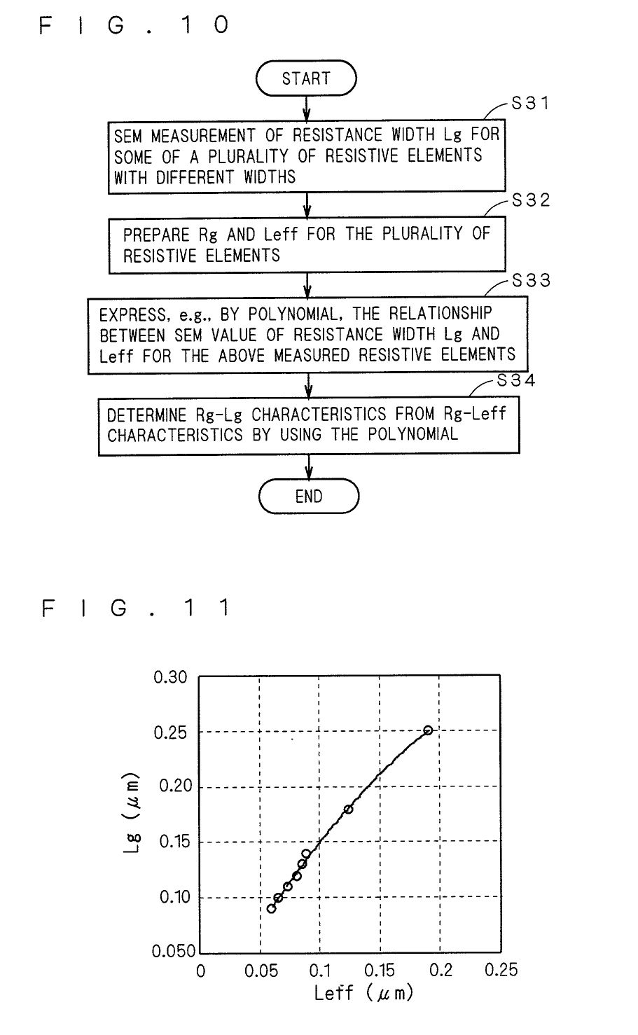

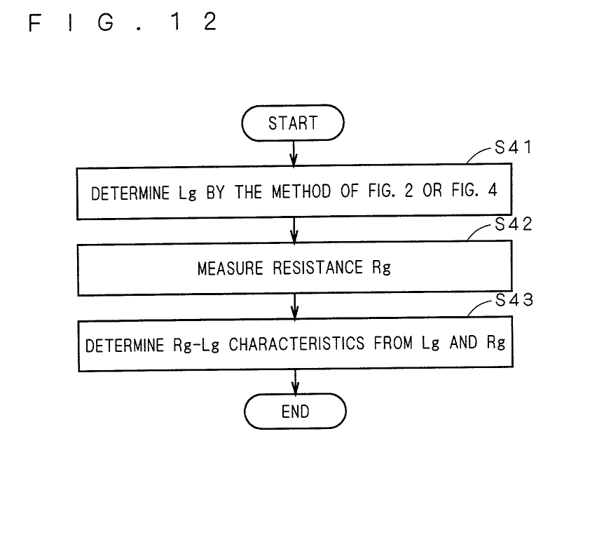

FIG. 2 is a flowchart of the semiconductor device evaluation method according to this preferred embodiment.

First, two or more insulated gate transistors with different design channel lengths are prepared. Those transistors are designed to have the same values for parameters including the fringing capacitance Cf, the gate overlap capacitance CGDO, the gate film thickness Tpoly, the gate insulating film thickness Tox, the permittivity εox of the gate insulating film, and the gate width W.

For each of the transistors prepared, the gate capacitance Cgi (i indicates the transistor number; the same can be said of the following description), the effective channel length Leffi, and the fringing capacitance Cf are determined by electrical measurement and/or calculation (step S01). The gate capacitance Cg here indicates the gate-to-substrate capacitance, which is equivalent to a parallel connection of electrostatic capacitances in the illustration of FIG. 1. That is, the following equation holds:

Cg={CGC+2(CGDO+Cf)}W (1)

The coefficient figure, 2, is derived in consideration of both the source and the drain. The capacitances CGC, CGDO, and Cf each are the capacitance per unit gate width.

To determine the gate capacitance Cg, an LCR meter, for example, can be used. More specifically, when the transistor 1 is of an n-channel type, the gate G should be connected to the “Hi” terminal of the LCR meter and the source/drain regions S and D should be connected in common to the “Low” terminal thereof, for measurement. At this time, a ground potential GND should be applied to the well B serving as a body electrode.

To determine the effective channel length Leff, a well-known technique, e.g., a technique disclosed in Japanese Patent Application No. 10-213019 (1998), can be used.

The fringing capacitance Cf can be determined by device simulation, for example. Or, it may be calculated from the following equation:

Cf=(2·εox/π)·ln (1+Tpoly/Tox) (2)

The source of Equation (2) is “MOSFET Models for VLSI Circuit Simulation Theory and Practice,” by Narain Arora, p. 112, Springer-Verlag Wien New York, 1993.

Since the fringing capacitance Cf is common among the transistors, the value for one transistor may be applied to the other transistors.

Next, the gate capacitance Cg and the effective channel length Leff are plotted and extended on a graph by extrapolation to determine gate-capacitance-vs.-effective-channel-length characteristics. Then, a gradient A and an intercept B of the characteristics are determined on the graph obtained by extrapolation (step S02). FIG. 3 shows an example of the extrapolation. This extrapolation should be carried out by linear approximation of the gate capacitance Cg and the effective channel length Leff, expressed by a linear function.

Upon consideration of the intercept B, the effective channel length Leff value of 0 indicates that theoretically, the gate capacitance Cg does not include the channel capacitance CGC in the case of FIG. 1. That is, the value of the intercept B equals 2(CGDO+Cf)·W. Accordingly, the following equation holds:

CGDO=B/(2·W)−Cf (3)

From this, the gate overlap capacitance CGDO is determined (step S03).

The gradient A represents the gate capacitance per unit channel length; therefore, in view of the equation for electrostatic capacitance of parallel plates, the following equation holds:

Toxeff=W·εox/A (4)

From this, the effective gate insulating film thickness Toxeff is determined (step S04).

The finished gate length Lg of the transistor can be determined by subtracting the fringing capacitance Cf from the gate capacitance Cg and dividing the result by the gate capacitance per unit channel length. That is, the finished gate length Lg can be determined from the following equation (step S05):

Lg=(Cgi−Cf)/A (5)

As above described, if the gate-capacitance-vs.-effective-channel-length characteristics are determined by extrapolation and the finished gate length Lg is determined from the gradient A of the characteristics, measurements can be performed without a conventional visual check using the SEM. This allows easy determination of the finished gate length Lg and prevents a measurer from being forced to expend a great deal of time and effort even when measuring a large number of points. Such measurements without a visual check can also prevent the occurrence of variations in measured values from measurer to measurer and allows the determination of the finished gate length Lg even if gate pattern does not appear on the semiconductor device surface.

The above extrapolation of the characteristics by linear approximation allows easy calculation of the gradient A of the characteristics and thereby accelerates the calculation of the finished gate length Lg. Further, the calculations of the gradient A and the intercept B allow easy determination of the gate overlap capacitance CGDO and the effective gate insulating film thickness Toxeff.

While in the above description, the finished gate length Lg is determined from the effective channel length Leff, the determination of the finished gate length Lg may be performed by using the design gate length Ld instead of the effective channel length Leff. FIG. 4 is a flowchart in such a case.

First, as in the case of FIG. 2, two or more insulated gate transistors with different design gate lengths Ldi (i indicates the transistor number) are prepared and the gate capacitance Cg and the fringing capacitance Cf are determined by electrical measurement and/or calculation (step S11).

The gate capacitance Cgi and the design gate length Ldi are then plotted on a graph and extended by extrapolation to determine gate-capacitance-vs.-design-gate-length characteristics. Then, the gradient A of the characteristics is determined on the graph obtained by extrapolation (step S12). FIG. 5 shows an example of the extrapolation. This extrapolation should also be carried out by linear approximation of the gate capacitance Cgi and the design channel length Ldi, expressed by a linear function.

Since the gradient A in this case represents the gate capacitance per unit gate length, Equation (4) can also be applied to determine the effective gate insulating film thickness Toxeff (step S13).

For the finished gate length Lg of the transistor, Equation (5) is applicable as it is, which offers ease of determination (step S14).

The aforementioned semiconductor device evaluation method can be achieved by a computer. FIG. 6 illustrates a configuration of a semiconductor device evaluation apparatus according to this preferred embodiment. This semiconductor device evaluation apparatus comprises an input section 4, such as a keyboard or a mouse, for information input from a user, an output section 5, such as a display or a printer, for information output to a user, a measuring device 2 for measuring the characteristics of an object to be measured 1, and a control section 3 for control of each section. The control section 3 is a functional component which operates according to a predetermined software program in a typical CPU (central processing unit) connected with a ROM (read only memory), a RAM (random access memory), and the like.

This semiconductor device evaluation apparatus further comprises a Leff determination section 11 for calculating the effective channel length Leff by, for example, a technique disclosed in Japanese Patent Application No. 10-213019 (1998), a Cf calculation/determination section 10 for calculating the fringing capacitance Cf from, for example, Equation (2), a Cg-Leff characteristics' gradient A/intercept B calculation section 9 for plotting and extrapolating gate-capacitance-vs.-effective-channel-length (Cg-Leff) characteristics on a graph and automatically calculating the gradient A and the intercept B, a CGDO determination section 8 for calculating the gate overlap capacitance CGDO, a Toxeff determination section 7 for calculating the effective gate insulating film thickness Toxeff, and a Lg determination section 6 for calculating the finished gate length Lg.

The Leff determination section 11, the Cf calculation/determination section 10, the Cg-Leff characteristics' gradient A/intercept B calculation section 9, the CGDO determination section 8, the Toxeff determination section 7, and the Lg determination section 6 may all be functional components like the control section 3, or they may be DSPs (digital signal processors) offering excellent computing power.

Now, how this semiconductor device evaluation apparatus performs the steps of FIG. 2 will be described hereinbelow.

First, in the step S01, the control section 3 receives a measured result of the gate capacitance Cgi from the measuring device 2 and also receives necessary information (the gate film thickness Tpoly, the gate insulating film thickness Tox, the permittivity εox of the gate insulating film, the gate width W, etc.) for calculation of the effective channel length Leffi and the fringing capacitance Cf from a user through the input section 4. The information received is transmitted as appropriate from the control section 3 to each section. For example, the Cf calculation/determination section 10 receives information including the gate film thickness Tpoly, the gate insulating film thickness Tox, and the permittivity εox of the gate insulating film and performs a calculation of Equation (2).

In the step S02, information including the gate capacitance Cgi and the effective channel length Leffi is transmitted from the control section 3 to the Cg-Leff characteristics' gradient A/intercept B calculation section 9. Then, the gate-capacitance-vs.-effective-channel-length characteristics are determined by plotting and extrapolation on graph and the gradient A and the intercept B are calculated.

In the steps S03 through S05, parameters such as the gradient A and the intercept B are fed to the CGDO determination section 8, the Toxeff determination section 7, and the Lg determination section 6. Those sections each perform a calculation using the parameters and return the result to the control section 3. The control section 3 outputs those values to the output section 5.

The steps of FIG. 4 can also be achieved by a semiconductor device evaluation apparatus as shown in FIG. 6. In that case, the Leff determination section 11 and the CGDO determination section 8 of FIG. 6 are omitted and the design gate length Ld is fed from the input section 4. Further, a calculation section (not shown) for calculating the gradient A of the gate-capacitance-vs.-design-gate-length characteristics should be provided instead of the Cg-Leff characteristics' gradient A/intercept B calculation section 9.

A program prepared for achieving the aforementioned semiconductor device evaluation method by a computer is executed either by itself or in combination with a preinstalled program in the computer. The program can be recorded on a computer-readable recording medium.

FIG. 7 shows an example of comparison between the finished gate length determined by the semiconductor device evaluation method of this preferred embodiment and the finished gate length obtained by the conventional SEM measurement. In FIG. 7, the horizontal axis indicates the measured sample number and the vertical axis indicates the finished gate length. The line DT1 indicates measured results by the SEM and the line DT2 indicates calculated results according to this preferred embodiment.

As is evident from FIG. 7, the calculated results according to this preferred embodiment can be judged as being fairly close to the measured results by the SEM. From this, while conventional techniques have attained measurement accuracy by a visual check of each sample, this preferred embodiment can attain the same degree of accuracy only by electrical measurement or calculation.

By applying the semiconductor device evaluation method of this preferred embodiment to the control of semiconductor device manufacturing, a semiconductor device manufacturing control method which allows easy checking and reappraisal of manufacturing conditions can also be achieved.

FIG. 8 is a flowchart of a semiconductor device manufacturing control method which applies the aforementioned semiconductor device evaluation method to manufacturing control. According to this semiconductor device manufacturing control method, after the manufacture of a semiconductor product (step S101), in-line measurements are made on the effective gate insulating film thickness Toxeff, the finished gate length Lg, and the like (step S102). This step S102 adopts the aforementioned semiconductor device evaluation method.

Each parameter measured is structured into a database (step S103) and the meeting of product standards is determined (step S104). For a conforming product, there has been no problem in the process of manufacturing the semiconductor product in step S101. A nonconforming product, on the other hand, requires checking and reappraisal of its manufacturing conditions in step S101.

The adoption of the aforementioned semiconductor device evaluation method in the step S102 reduces the time involved in measurement of each parameter without sacrificing accuracy and allows easy checking and reappraisal of manufacturing conditions.

It goes without saying that the semiconductor device evaluation method of this preferred embodiment is applicable to a semiconductor device manufacturing method. In that case, the semiconductor device manufacturing method requires only the steps S101, S102, and S104 of FIG. 8, wherein nonconforming products obtained in step S104 should be rejected as defectives. This allows easy checking of nonconforming products.

### Second Preferred Embodiment

In this preferred embodiment, with a plurality of insulated gate transistors with different gate lengths (line widths Lg) taken as a plurality of resistive elements using the gates as resistances, the line width Lg, the gate resistance Rg, and the effective channel length Leff are measured for some of those transistors to determine line-width-vs.-effective-channel-length characteristics. The characteristics obtained are used to determine the characteristics between the line width Lg and the resistance Rg for all of the plurality of resistive elements. This provides a semiconductor device evaluation method and apparatus which allows easy checking of whether all of a plurality of resistive elements have been manufactured properly. By applying such an evaluation method and apparatus to manufacturing control, a semiconductor device manufacturing control method which allows easy reappraisal of manufacturing conditions can also be achieved.

In this preferred embodiment, also, the insulated gate transistor 1 is adopted as an object to be measured. In recent insulated gate transistor structures, for example, a silicide layer is generally formed in the source region S, the drain region D, and the gate G in order to reduce resistance. However, as the gate length becomes shorter, the formation of a silicide layer often becomes more difficult. This is because too short a gate length prevents the formation of a proper silicide layer and tends to cause a wire-break in a silicide layer.

In this preferred embodiment, the characteristics between the resistance Rg and the line width Lg of the gate are determined; therefore, a judgment for example about to what extent the line width Lg can be reduced to form a proper silicide layer, can be made.

FIG. 10 is a flowchart of the semiconductor device evaluation method according to this preferred embodiment.

First, the line width Lg is measured for some of a plurality of resistive elements with different line widths Lg (i.e., elements using as resistances the gates of a plurality of insulated gate transistors with different gate lengths Lg). For the measurement of the line width Lg, a SEM, for example, should be used as in the conventional case (step S31). The transistors are designed to have the same values for parameters including the fringing capacitance Cf, the gate overlap capacitance CGDO, the gate film thickness Tpoly, the gate insulating film thickness Tox, the permittivity εox of the gate insulating film, and the gate width W.

The use of the SEM involves the aforementioned conventional problems; however, the problem (1) can be resolved here because the SEM measures the line width Lg for not all but only some of the plurality of resistive elements.

Then, for all of the plurality of transistors prepared, the resistance Rg and the effective channel length Leff are determined by electrical measurement and/or calculation (step S32). The resistance Rg here indicates the resistance of the gate G across the line width thereof and it can be measured by providing terminals X and Y at both ends of the gate G forming a fine wire.

The effective channel length Leff is the same as described in the first preferred embodiment and it can be determined by using, for example, a technique disclosed in Japanese Patent Application No. 10-213019 (1998).

Next, the line widths Lg and the effective channel length Leff for some of the resistive elements, which have been determined by SEM measurements in the step S31, are plotted and extended by extrapolation on a graph thereby to determine the line-width-vs.-effective-channel-width characteristics, which can be expressed by a polynomial, for example (step S33). FIG. 11 shows an example of the extrapolation. In the case of FIG. 11, the polynomial obtained by extrapolation is as follows:

Lg=−2.78 Leff²+1.91 Leff−0.014 (6)

Then, the relationship between the resistance Rg and the effective channel length Leff (Rg-Leff characteristics) for each of the plurality of resistive elements is referred to at each point on the graph obtained by the extrapolation, thereby to determine the characteristics between the line width Lg and the resistance Rg (Rg-Lg characteristics) for all of the plurality of resistive elements (step S34).

In this way, the characteristics between the line width Lg and the resistance Rg for all of the plurality of resistive elements are determined by using the line-width-vs.-effective-channel-length characteristics for some of the plurality of resistive elements. This allows easy checking of whether all of the plurality of resistive elements have been manufactured properly.

While in the above description, the Lg-Rg characteristics are determined by using the line width Lg obtained by the SEM measurement, the line width Lg may be substituted with the finished gate length obtained in the first preferred embodiment. FIG. 12 is a flowchart in such a case.

As in the first preferred embodiment (as in the flowchart of either FIG. 2 or 4), the finished gate length Lg is determined (step S41).

Then, the resistance Rg is measured for all of a plurality of resistive elements (step S42).

The resistance Rg obtained and the finished gate length Lg are then plotted on a graph to determine the characteristics therebetween (step S43).

This method also allows easy checking of whether a plurality of insulated gate transistors have been manufactured properly.

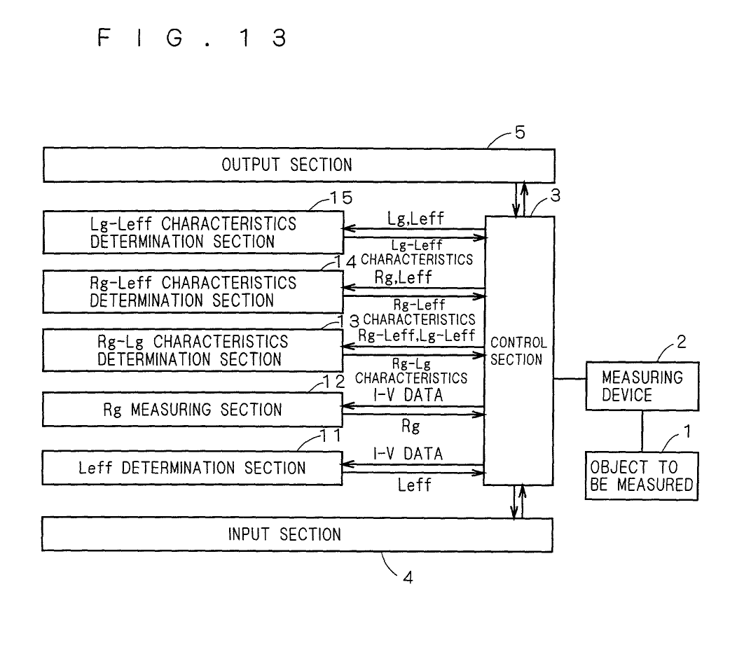

The aforementioned semiconductor device evaluation method can be achieved by a computer. FIG. 13 illustrates a configuration of a semiconductor device evaluation apparatus which achieves the semiconductor device evaluation method shown in FIG. 10. This semiconductor device evaluation apparatus comprises the input section 4, such as a keyboard or a mouse, for information input from a user, the output section 5, such as a display or a printer, for information output to a user, the measuring device 2 for measuring the characteristics of the object to be measured 1, and the control section 3 for control of each section. The control section 3 is a functional component which operates according to a predetermined software program in a typical CPU connected with a ROM, a RAM, and the like.

The semiconductor device evaluation apparatus further comprises the Leff determination section 11 for calculating the effective channel length Leff by using, for example, a technique disclosed in Japanese Patent Application No. 10-213019 (1998), a Rg measuring section 12 for measuring the resistance Rg from, for example, current-voltage (I-V) data received from the measuring device 2, a Rg-Leff characteristics determination section 14 for determining the resistance-vs.-effective-channel-length characteristics, a Lg-Leff characteristics determination section 15 for determining the line-width-vs.-effective-channel-length characteristics, and a Rg-Lg characteristics determination section 13 for determining the resistance-vs.-finished-gate-length characteristics from both the resistance-vs.-effective-channel-length characteristics and the line-width-vs.-effective-channel-length characteristics.

The Leff determination section 11, the Rg measuring section 12, the Rg-Lg characteristics determination section 13, the Rg-Leff characteristics determination section 14, and the Lg-Leff characteristics determination section 15 may all be functional components like the control section 3, or they may be DSPs having excellent computing power.

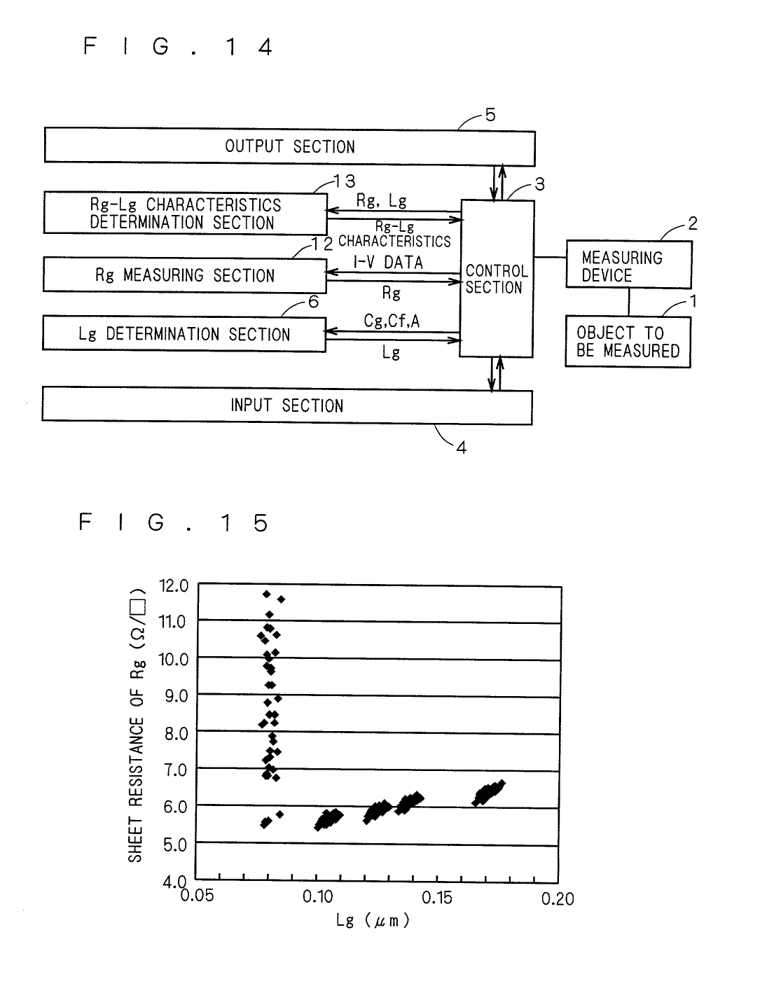

FIG. 14 illustrates a configuration of a semiconductor device evaluation apparatus which achieves the semiconductor device evaluation method shown in FIG. 12. This semiconductor device evaluation apparatus comprises part of the constituents of the semiconductor device evaluation apparatus shown in FIG. 13; more specifically, it comprises the measuring device 2, the control section 3, the input section 4, the output section 5, the Rg measuring section 12, and the Rg-Lg characteristics determination section 13. The function of each section is above described. This semiconductor device evaluation apparatus further comprises the Lg determination section 6 shown in FIG. 6.

Now, how the semiconductor device evaluation apparatus of FIG. 13 performs the steps of FIG. 10 will be described hereinbelow.

In step S31, SEM data including the line widths Lg of the resistances (gates) for some of the objects to be measured 1 are received from the input section 4.

In step S32, the measuring device 2 measures I-V data and the Rg measuring section 12 measures the resistance Rg, for all of the plurality of resistive elements, for example. The Leff determination section 11 calculates the effective channel length Leff from the I-V data. At the same time, the Rg-Leff characteristics determination section 14 determines the resistance-vs.-effective-channel-length characteristics.

In step S33, the Lg-Leff characteristics determination section 15 receives data including the line widths Lg of the resistances for the above some of the resistive elements and data including corresponding effective channel lengths Leff, and determines the line-width-vs.-effective-channel-length characteristics by plotting and extrapolation on a graph.

In step S34, the Rg-Lg characteristics determination section 13 receives the resistance-vs.-effective-channel-length characteristics and the line-width-vs.-effective-channel-length characteristics to determine the resistance-vs.-finished-gate-length characteristics. The Rg-Lg characteristics determination section 13 then outputs the resistance-vs.-finished-gate-length characteristics to the output section 5.

The semiconductor device evaluation apparatus of FIG. 14 performs the steps of FIG. 12 as follows:

First, the Lg determination section 6 performs step S41.

In step S42, the measuring device 2 measures I-V data for all of a plurality of resistive elements, and the Rg measuring section 12 measures the resistance Rg.

In step S43, the Rg-Lg characteristics determination section 13 determines the resistance-vs.-finished-gate-length characteristics from data including the resistance Rg and the finished gate length Lg. The Rg-Lg characteristics determination section 13 outputs the resistance-vs.-finished-gate-length characteristics to the output section 5.

A program prepared for achieving the aforementioned semiconductor device evaluation method by a computer is executed either by itself or in combination with a preinstalled program in the computer. The program can be recorded on a computer-readable recording medium.

FIG. 15 shows an example of the resistance-vs.-finished-gate-length characteristics data obtained by the semiconductor device evaluation method of this preferred embodiment. In FIG. 15, the horizontal axis indicates the finished gate length Lg and the vertical axis indicates the sheet resistance of the resistance Rg.

As is evident from FIG. 15, for the finished gate length Lg of 0.10 μm or more, the resistance Rg data for every sample are united in a mass, while for the finished gate length of less than 0.10 μm, the resistance Rg data vary from sample to sample. This is probably because, as above described, a shorter gate length makes the formation of a proper silicide layer in the gate more difficult and thereby causes variations in the resistance values from sample to sample.

In this preferred embodiment, the characteristics between the resistance Rg and the finished gate length Lg are determined, which makes it possible to evaluate to what extent the finished gate length should be reduced to cause variations in the gate resistance.

In FIG. 15, units of data points for the finished gate length of 0.10 μm or more extend linearly with the finished gate length. This is probably because since, as the finished gate length decreases, the silicide layer is formed rounder and larger than the design value and thereby has a lower resistance value.

The semiconductor device evaluation method according to this preferred embodiment is also applicable to the semiconductor device manufacturing control method shown in FIG. 8. In that case, “verification of the resistance versus finished gate length characteristics” should be conducted instead of the in-line measurements of Toxeff and Lg in the step S102.

By so doing, the semiconductor device manufacturing control method which allows easy checking and reappraisal of manufacturing conditions can be achieved.

Similarly, it is also possible to achieve a semiconductor device manufacturing method which applies the semiconductor device evaluation method of this preferred embodiment. This semiconductor device manufacturing method allows easy checking of nonconforming products.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device evaluation method comprising the steps of:
(a) for a plurality of insulated gate transistors with different channel lengths, determining an effective channel length Leff, a gate capacitance Cg which is a capacitance between a gate and a substrate, and a fringing capacitance Cf which is a capacitance between said gate and a portion of said substrate not covered with said gate, by electrical measurement and/or calculation;
(b) plotting said gate capacitance Cg and said effective channel length Leff, which have been determined in said step (a), on a graph and extending the same by extrapolation on said graph to determine gate-capacitance-vs.-effective-channel-length characteristics; and
(c) calculating a gradient A of said gate-capacitance-vs.-effective-channel-length characteristics and determining a finished gate length Lg for each of said plurality of insulated gate transistors from the equation, Lg=(Cg−Cf)/A.

2. The semiconductor device evaluation method according to claim 1, wherein
said step (a) prepares a design gate length Ld instead of determining said effective channel length Leff by electrical measurement and/or calculation,
said step (b) plots said gate capacitance Cg and said design gate length Ld, which have been determined in said step (a), on a graph and extends the same by extrapolation on said graph to determine gate-capacitance-vs.-design-gate-length instead of determining said gate-capacitance-vs.-effective-channel-length characteristics, and
said step (c) calculates a gradient of said gate-capacitance-vs.-design-gate-length characteristics as said gradient A, instead of calculating the gradient of said gate-capacitance-vs.-effective-channel-length characteristics.

3. The semiconductor device evaluation method according to claim 1, wherein
said step (b) carries out said extrapolation of said characteristics by linear approximation.

4. The semiconductor device evaluation method according to claim 1, further comprising the steps of:
(d) determining an intercept B of said gate-capacitance-vs.-effective-channel-length characteristics; and
(e) for said plurality of insulated gate transistors, determining a gate overlap capacitance CGDO which is a capacitance between said gate and a source/drain region covered with said gate, from the equation, CGDO=B/(2·W)−Cf, by using a gate width W of said gate.

5. The semiconductor device evaluation method according to claim 1, further comprising the step of:
(f) for said plurality of insulated gate transistors, determining an effective gate insulating film thickness Toxeff from the equation, Toxeff=W·εox/A, by using said gradient A, a gate width W of said gate, and the permittivity εox of a gate insulating film.

6. A computer-readable recording medium for recording a program which is executed by a computer either by itself or in combination with a preinstalled program in said computer, to carry out said semiconductor device evaluation method according to claim 1.

7. A semiconductor device evaluation apparatus comprising:
a calculation section for, for a plurality of insulated gate transistors with different channel lengths, plotting an effective channel length Leff and a gate capacitance Cg which is a capacitance between a gate and a substrate, on a graph and extending the same by extrapolation on said graph to determine gate-capacitance-vs.-effective-channel-length characteristics, and calculating a gradient A of said characteristics;
a first determination section for determining a finished gate length Lg for each of said plurality of insulated gate transistors from the equation, Lg=(Cg−Cf)/A, by using a fringing capacitance Cf which is a capacitance between said gate and a portion of said substrate not covered with said gate, said gradient A, and said gate capacitance Cg; and
a control section for controlling said calculation section and said first determination section.

8. The semiconductor device evaluation apparatus according to claim 7, wherein
said calculation section uses a design gate length Ld instead of said effective channel length Leff,
said calculation section plots said gate capacitance Cg and said design gate length Ld on a graph and extends the same by extrapolation on said graph to determine gate-capacitance-vs.-design-gate-length characteristics, instead of determining said gate-capacitance-vs.-effective-channel-length characteristics, and
said calculation section calculates a gradient of said gate-capacitance-vs.-design-gate-length characteristics as said gradient A, instead of calculating the gradient of said gate-capacitance-vs.-effective-channel-length characteristics.

9. The semiconductor device evaluation apparatus according to claim 7, wherein
said calculation section carries out said extrapolation of said characteristics by linear approximation.

10. The semiconductor device evaluation apparatus according to claim 7, wherein
said calculation section further determines an intercept B of said gate-capacitance-vs.-effective-channel-length characteristics,
said apparatus further comprising:
a second determination section for, for said plurality of insulated gate transistors, determining a gate overlap capacitance CGDO which is a capacitance between said gate and a source/drain region covered with said gate, from the equation, CGDO=B/(2·W)−Cf, by using a gate width W of said gate,
wherein said second determination section is also controlled by said control section.

11. The semiconductor device evaluation apparatus according to claim 7, further comprising:
a third determination section for, for said plurality of insulated gate transistors, determining an effective gate insulating film thickness Toxeff from the equation, Toxeff=W·εox/A, by using said gradient A, a gate width W of said gate, and the permittivity εox of a gate insulating film,
wherein said third determination section is also controlled by said control section.

12. A semiconductor device evaluation method comprising the steps of:
(a) while regarding a plurality of insulated gate transistors with different gate length as a plurality of resistive elements with different line widths Lg each using a gate as a resistance, determining said line width Lg for some of said plurality of resistive elements;
(b) for all of said plurality of resistive elements, determining a resistance Rg of said gate and an effective channel length Leff by electrical measurement and/or calculation;
(c) plotting said line width Lg and said effective channel length Leff, which have been determined in said steps (a) and (b), on a graph and extending the same by extrapolation on said graph to determine line-width-vs.-effective-channel-width characteristics; and
(d) for all of said plurality of resistive elements, determining characteristics between said line width Lg and said resistance Rg by using said line-width-vs.-effective-channel-length characteristics.

13. A semiconductor device evaluation method comprising the steps of:
(g) preparing a finished gate length Lg determined by said semiconductor device evaluation method according to claim 1;
(h) for each of said plurality of insulated gate transistors, determining a resistance Rg of a gate by electrical measurement and/or calculation; and
(i) determining characteristics between said finished gate length Lg and said resistance Rg.

14. A computer-readable recording medium for recording a program which is executed by a computer either by itself or in combination with a preinstalled program in said computer, to carry out said semiconductor device evaluation method according to claim 12.

15. A semiconductor device evaluation apparatus comprising:
a calculation section for, while regarding a plurality of insulated gate transistors with different channel lengths as a plurality of resistive elements with different line widths Lg each using a gate as a resistance, plotting an effective channel length Leff and said line width Lg for some of said plurality of resistive elements on a graph and extending the same by extrapolation on said graph to determine line-width-vs.-effective-channel-length characteristics;
a determination section for, for all of said plurality of resistive elements, determining characteristics between said line width Lg and a resistance Rg of said gate by using said line-width-vs.-effective-channel-length characteristics; and
a control section for controlling said calculation section and said determination section.

16. A semiconductor device evaluation apparatus comprising:
a determination section for determining characteristics between a finished gate length Lg obtained by said semiconductor device evaluation method according to claim 1, and a resistance Rg of a gate for each of said plurality of insulated gate transistors; and
a control section for controlling said determination section.

17. A semiconductor device manufacturing control method comprising:
a judgment step for judging whether said finished gate length Lg of each of said plurality of insulated gate transistors, obtained by said semiconductor device evaluation method according to claim 1, meets required standard,
wherein a result of judgment in said judgment step is utilized for reappraisal of manufacturing conditions of semiconductor devices.

18. A semiconductor device manufacturing method comprising
a judgment step for judging whether said finished gate length Lg of each of said plurality of insulated gate transistors, obtained by said semiconductor device evaluation method according to claim 1, meets required standards,
wherein a result of judgment in said judgment step is utilized for rejection of nonconforming products.

19. A semiconductor device manufacturing control method comprising:
a judgment step for judging whether said resistance Rg of each of said plurality of insulated gate transistors, obtained by said semiconductor device evaluation method according to claim 12, meets required standards,
wherein a result of judgment in said judgment step is utilized for reappraisal of manufacturing conditions of semiconductor devices.

20. A semiconductor device manufacturing method comprising:
a judgment step for judging whether said resistance Rg of each of said plurality of insulated gate transistors, obtained by said semiconductor device evaluation method according to claim 12, meets required standards,
wherein a result of judgment in said judgment step is utilized for rejection of nonconforming products.
